(19) United States
(12) Patent Application Publication
(10) Pub. No.: US 2025/0210430 A1
(43) Pub. Date: Jun. 26, 2025

(54) SEMICONDUCTOR PACKAGE AND METHOD FOR MANUFACTURING THE SAME

(71) Applicant: Samsung Electronics Co., Ltd., Suwon-si (KR)

(72) Inventor: DAE HYUN KIM, Suwon-si (KR)

(21) Appl. No.: 18/760,073

(22) Filed: Jul. 1, 2024

(30) Foreign Application Priority Data
Dec. 22, 2023 (KR) 10-2023-0189902

(51) Int. Cl. H01L 23/29; H01L 23/00; H01L 23/31; H01L 23/498; H01L 23/538; H01L 25/065

(52) U.S. Cl. CPC H01L 23/295; H01L 23/3107; H01L 23/49816; H01L 23/5383; H01L 24/32; H01L 24/33; H01L 24/48; H01L 24/73; H01L 25/0657; H01L 2224/32145; H01L 2224/32225; H01L 2224/33181; H01L 2224/48227; H01L 2224/73265; H01L 2225/0651

(57) ABSTRACT

A semiconductor package including a molding layer and a method for manufacturing the same are provided. The semiconductor package includes a package substrate, a semiconductor chip mounted on the package substrate, and a molding layer on the semiconductor chip on the package substrate, the molding layer including a first filler having a first size and a second filler having a second size larger than the first size, wherein the molding layer includes a first area on an upper surface of the semiconductor chip, and a second area on a side surface of the first area, and wherein a ratio of a first content percentage of the first filler and a first content percentage of the second filler in the first area is different from a ratio of a second content percentage of the first filler and a second content percentage of the second filler in the second area.

### CROSS-REFERENCE TO RELATED APPLICATIONS

This application claims priority from Korean Patent Application No. 10-2023-0189902 filed on Dec. 22, 2023 in the Korean Intellectual Property Office, and all the benefits accruing therefrom under 35 U.S.C. 119, the contents of which in its entirety are herein incorporated by reference.

### BACKGROUND OF THE INVENTION

### Technical Field

The present disclosure relates to a semiconductor package and a method for manufacturing the same. More specifically, the present disclosure relates to a semiconductor package including a molding layer and a method for manufacturing the same.

### Description of Related Art

With the rapid development of the electronics industry and user demands, an electronic device is becoming more compact, lightweight, and multi-functional, and a semiconductor package used in the electronic device may also become miniaturized, lightweight, and multi-functional. Accordingly, a molding material that seals the semiconductor package is emerging as an important element.

EMC (Epoxy Molding Compound) as a thermosetting resin may be used as the molding material for the semiconductor package. A composition of the epoxy molding compound may vary depending on formability, moisture resistance, adhesiveness, mechanical properties, thermal properties, and/or electrical properties.

### SUMMARY OF THE INVENTION

Aspects of the present disclosure provide a semiconductor package with improved strength.

Aspects of the present disclosure provide a method for manufacturing a semiconductor package with increased strength.

However, aspects of the present disclosure are not restricted to the one set forth herein. The above and other aspects of the present inventive concept will become more apparent to one of ordinary skill in the art to which the present disclosure pertains by referencing the detailed description of the present inventive concept given below.

According to an aspect of the present disclosure, there is provided a semiconductor package comprising a package substrate, a semiconductor chip mounted on the package substrate, and a molding layer on the semiconductor chip on the package substrate, the molding layer including a first filler having a first size and a second filler having a second size larger than the first size, wherein the molding layer includes a first area on an upper surface of the semiconductor chip, and a second area on a side surface of the first area, and wherein a ratio of a first content percentage of the first filler and a first content percentage of the second filler in the first area is different from a ratio of a second content percentage of the first filler and a second content percentage of the second filler in the second area.

According to an aspect of the present disclosure, there is provided a semiconductor package comprising a package substrate, a semiconductor chip mounted on the package substrate, and a molding layer on the semiconductor chip on the package substrate, the molding layer including a first filler having a first size and a second filler having a second size larger than the first size, wherein the molding layer includes a first area on an upper surface of the semiconductor chip, and a second area surrounding a side surface of the semiconductor chip and a side surface of the first area, wherein in the first area, a first content percentage of the first filler is greater than a first content percentage of the second filler, and wherein in the second area, a second content percentage of the second filler is greater than a second content percentage of the first filler.

A semiconductor package, according to some embodiments herein, may include a package substrate and a semiconductor chip on the package substrate. Moreover, the semiconductor package may include a molding layer on an upper surface and a side surface of the semiconductor chip, and on an upper surface of the package substrate. The molding layer may include small fillers having a narrow diameter and large fillers having a wide diameter. A first portion of the molding layer that vertically overlaps the upper surface of the semiconductor chip may have a high concentration of the small fillers and a low concentration of the large fillers. A second portion of the molding layer that horizontally overlaps the side surface of the semiconductor chip may have a low concentration of the small fillers and a high concentration of the large fillers.

According to an aspect of the present disclosure, there is provided a method for manufacturing a semiconductor package, the method comprising providing a first mold having a cavity defined therein, placing a molding material into the cavity, the molding material including a first filler having a first size and a second filler having a second size greater than the first size, and the first filler and the second filler having different surface charges from each other, forming a first area and a second area in the molding material using an electrophoretic effect such that a ratio of a first content percentage of the first filler and a first content percentage of the second filler in the first area is different from a ratio of a second content percentage of the first filler and a second content percentage of the second filler in the second area, providing a second mold having a semiconductor chip thereon, on the first mold, and forming a molding layer on the semiconductor chip from the molding material using the first mold and the second mold.

Specific details of other embodiments are included in the detailed description and drawings.

### BRIEF DESCRIPTION OF DRAWINGS

The above and other aspects and features of the present disclosure will become more apparent by describing in detail some embodiments thereof with reference to the attached drawings, in which:

FIG. 1 is an example layout diagram for illustrating a semiconductor package according to some embodiments.

FIG. 2 is a schematic cross-sectional view taken along line A-A in FIG. 1.

FIGS. 3 to 6 are various schematic cross-sectional views illustrating semiconductor packages according to some embodiments, respectively.

FIG. 7 is an example layout diagram for illustrating a semiconductor package according to some embodiments.

FIG. 8 is a schematic cross-sectional view taken along line B-B in FIG. 7.

FIGS. 9 to 17 are diagrams of intermediate structures corresponding to intermediate steps of a method for manufacturing a semiconductor package according to some embodiments.

FIG. 18 is a diagram of an intermediate structure corresponding to an intermediate step of a method for manufacturing a semiconductor package according to some embodiments.

### DETAILED DESCRIPTION

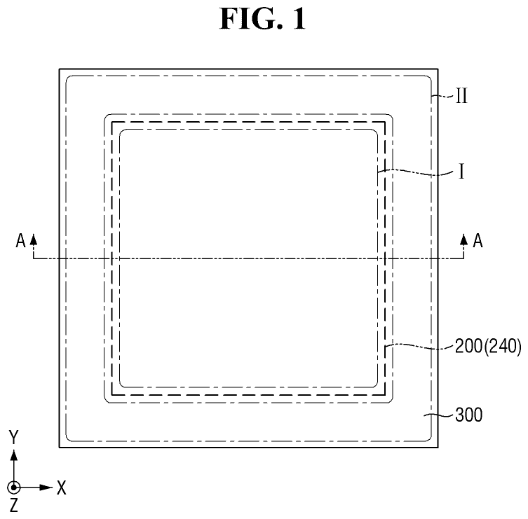

Hereinafter, a semiconductor package according to some embodiments will be described with reference to FIGS. 1 to 8.

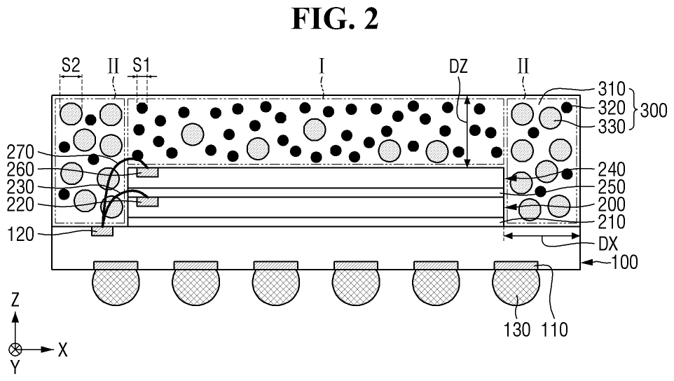

FIG. 1 is an example layout diagram for illustrating a semiconductor package according to some embodiments. FIG. 2 is a schematic cross-sectional view taken along line A-A in FIG. 1.

Referring to FIG. 1 and FIG. 2, a semiconductor package according to some embodiments includes a package substrate 100, a contact terminal 130, a first semiconductor chip 200, a second semiconductor chip 240, and a molding layer 300.

The package substrate 100 may be a substrate for the semiconductor package. For example, the package substrate 100 may be embodied as a printed circuit board (PCB). Alternatively, the package substrate 100 may be a ceramic substrate or an interposer, or may be a semiconductor chip including a semiconductor device. The package substrate 100 may be provided as a support substrate of the semiconductor package.

The package substrate 100 may include a first substrate pad 110 and a second substrate pad 120. The first substrate pad 110 may not be covered with a surface (e.g., an upper surface or a lower surface) of the package substrate 100 so as to be exposed (e.g., so that the contact terminal 130 can contact the first substrate pad 110). The second substrate pad 120 may not be covered with a surface (e.g., a lower surface or an upper surface) of the package substrate 100 so as to be exposed (e.g., so that one or more bonding wires can contact the second substrate pad 120). The first substrate pad 110 and the second substrate pad 120 may be electrically connected to each other via wirings disposed inside the package substrate 100.

The contact terminal 130 may be disposed on the lower surface of the package substrate 100. The contact terminal 130 may be electrically connected to the package substrate 100. For example, the contact terminal 130 may be attached to the first substrate pad 110 of the package substrate 100. The contact terminal 130 may be embodied as, for example, a solder ball or a bump. However, embodiments of the present disclosure are not limited thereto. The package substrate 100 may be electrically connected to an external electronic device, etc., via the contact terminal 130.

The first semiconductor chip 200 may be disposed on the package substrate 100. For example, a first attachment film 210 may be formed on the upper surface of the package substrate 100. The first semiconductor chip 200 may be attached to the package substrate 100 via the first attachment film 210. The first attachment film 210 may include, for example, liquid epoxy, adhesive tape, or a conductive medium. However, embodiments of the present disclosure are not limited thereto. For example, the first attachment film 210 may include a die attach film (DAF).

The first semiconductor chip 200 may be electrically connected to the package substrate 100. In some embodiments, a first bonding wire 230 may be formed to connect the package substrate 100 and the first semiconductor chip 200 to each other. For example, the first semiconductor chip 200 may include a first chip pad 220 not covered with an upper surface of the first semiconductor chip 200 so as to be exposed (e.g., so that the first bonding wire 230 can contact the first chip pad 220). The first bonding wire 230 may electrically connect the second substrate pad 120 of the package substrate 100 and the first chip pad 220 of the first semiconductor chip 200 to each other. Thus, the first semiconductor chip 200 may be mounted on the package substrate 100.

The second semiconductor chip 240 may be disposed on the first semiconductor chip 200. For example, a second attachment film 250 may be formed on an upper surface of the first semiconductor chip 200. The second semiconductor chip 240 may be attached to the first semiconductor chip 200 via the second attachment film 250. The second attachment film 250 may include, for example, liquid epoxy, adhesive tape, or a conductive medium. However, embodiments of the present disclosure are not limited thereto. For example, the second attachment film 250 may include a die attach film (DAF).

The second semiconductor chip 240 may be electrically connected to the package substrate 100 and/or the first semiconductor chip 200. In some embodiments, a second bonding wire 270 may be formed to connect the package substrate 100 and the second semiconductor chip 240 to each other. For example, the second semiconductor chip 240 may include a second chip pad 260 not covered with an upper surface of the second semiconductor chip 240 so as to be exposed (e.g., so that the second bonding wire 270 can contact the second chip pad 260). The second bonding wire 270 may electrically connect the second substrate pad 120 of the package substrate 100 and the second chip pad 260 of the second semiconductor chip 240 to each other. Thus, the second semiconductor chip 240 may be mounted on the package substrate 100.

It is shown that the number of semiconductor chips 200 and 240 mounted on the package substrate 100 is two. However, this is only an example, and three or more semiconductor chips may be mounted on the package substrate 100.

Furthermore, the semiconductor chips 200 and 240 are shown as only being stacked on top of each other in an aligned manner in which sidewalls of the second semiconductor chip 240 are aligned with sidewalls of the first semiconductor chip 200. However, this is only an example. In another example, the semiconductor chips 200 and 240 may be stacked in an overhang structure (e.g., in a stepped manner).

Furthermore, the semiconductor chips 200 and 240 are shown as being electrically connected to the package substrate 100 only via the bonding wires 230 and 270. However, this is only an example. In another example, the semiconductor chips 200 and 240 may be electrically connected to the package substrate 100 via a bonding tape, or may be electrically connected to the package substrate 100 in a flip chip bonding scheme.

The molding layer 300 may be formed on the package substrate 100 so as to be on (e.g., cover) the first semiconductor chip 200 and the second semiconductor chip 240. For example, the molding layer 300 may cover an upper surface of the package substrate 100, a side surface of the first semiconductor chip 200, and a side surface and an upper surface of the second semiconductor chip 240.

The molding layer 300 may include epoxy molding compound (EMC) as a thermosetting resin. For example, the molding layer 300 may include a molding resin 310 including an epoxy resin, and first fillers 320 and second fillers 330 dispersed in the molding resin 310. For example, the molding layer 300 may have a structure in which the first filler 320 and the second filler 330 are dispersed in a matrix formed by curing a liquid crystalline epoxy compound with a curing agent.

The curing agent may include, but is not limited to, at least one of a phenolic curing agent, a cationic curing agent, an acrylic curing agent, and an anhydride curing agent.

Each of the first filler 320 and the second filler 330 may include, for example, at least one of silica (SiO₂), alumina (Al₂O₃), silicon nitride (Si₃N₄), boron nitride (BN), aluminum nitride (AlN), diamond, and combinations thereof. However, embodiments of the present disclosure are not limited thereto. The first filler 320 and the second filler 330 may include the same material or may include different materials. For example, each of the first filler 320 and the second filler 330 may include silica.

In some embodiments, based on 100% by weight (i.e., based on a total weight) of the molding layer 300, a content of the fillers 320 and 330 may be about 50% by weight or greater. For example, based on 100% by weight of the molding layer 300, the content of the fillers 320 and 330 may be in a range of about 50% by weight to about 90% by weight. In the above content range, physical properties such as the formability, low stress, high-temperature strength, rigidity, coefficient of thermal expansion (CTE), etc., of the molding layer 300 may be adjusted appropriately.

The first filler 320 and the second filler 330 may have different sizes (e.g., different average particle diameters). For example, the first filler 320 may have a first size S1, and the second filler 330 may have a second size S2 larger than the first size S1. The sizes S1, S2 may be respective diameters.

In some embodiments, the average particle diameter of the first filler 320 may be about 20 micrometers (μm) or smaller, and the average particle diameter of the second filler 330 may be about 20 μm or greater. For example, the average particle diameter of the first filler 320 may be in a range of about 0.1 μm to about 20 μm, and the average particle diameter of the second filler 330 may be in a range of about 20 μm to about 80 μm. The second filler 330 may thus have a wider diameter than the first filler 320.

In some embodiments, in an entire (i.e., total) area of the molding layer 300, a content percentage of the second filler 330 may be greater than a content percentage of the first filler 320. In this regard, the content percentage means a weight percent (wt %) based on 100% by weight of the molding layer 300. For example, in an entire area of the molding layer 300, a ratio of the content percentage of the first filler 320 and the content percentage of the second filler 330 may be in a range of about 1:9 to about 4:6. Alternatively, for example, in an entire area of the molding layer 300, the ratio of the content percentage of the first filler 320 and the content percentage of the second filler 330 may be about 2:8 to about 4:6.

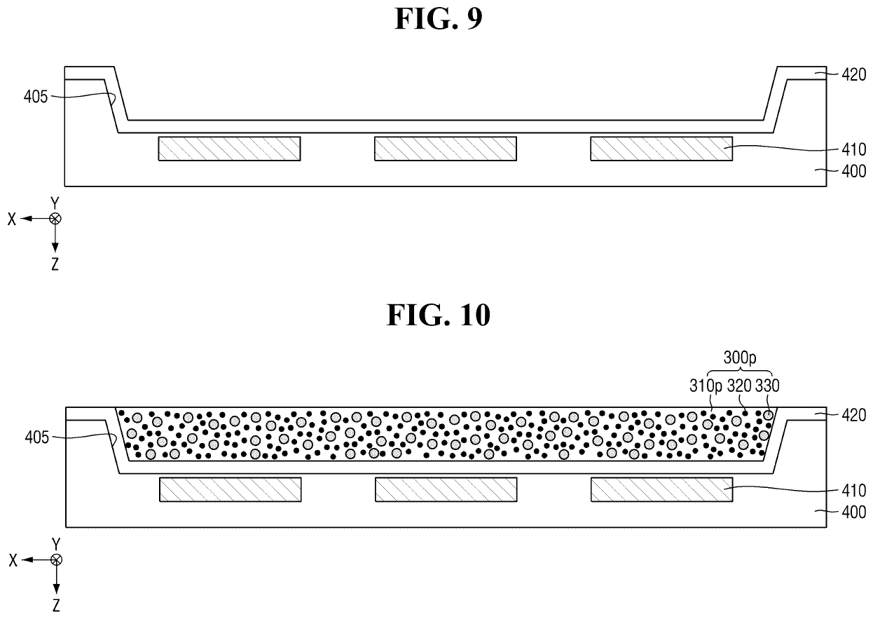

In some embodiments, the first filler 320 and the second filler 330 may have different surface charges. For example, the surface charge of the first filler 320 may be negative (−), and the surface charge of the second filler 330 may be neutral. This will be described in more detail later in the description of FIGS. 9 to 18.

The molding layer 300 may include a first area I (e.g., a first portion) and a second area II (e.g., a second portion) different from each other.

At least a portion of the first area I may be disposed on the upper surfaces of the semiconductor chips 200 and 240. The first area I may cover at least a portion of the upper surface of the second semiconductor chip 240. For example, at least a portion of the first area I may overlap the semiconductor chips 200 and 240 in a vertical direction (e.g., a third direction Z) that intersects the upper surface of the package substrate 100. A thickness of the first area I may be, for example, in a range of about 100 μm to about 2 millimeters (mm). For example, a first distance DZ from the upper surface of the second semiconductor chip 240 to an upper surface of the molding layer 300 in the third direction Z may be in a range of about 100 μm to about 2 mm.

At least a portion of the second area II may be disposed on a side surface of the first area I. The second area II may cover at least a portion of the side surface of each of the semiconductor chips 200 and 240. For example, at least a portion of the second area II may overlap with the semiconductor chips 200 and 240, and the first area I, in a horizontal direction (e.g., a first direction X or a second direction Y) parallel to the upper surface of the package substrate 100. In some embodiments, the second area II may surround the side surface of each of the semiconductor chips 200 and 240 and the side surface of the first area I in a plan view (e.g., in an XY plane). A thickness of the second area II may be, for example, in a range of about 100 μm to about 10 mm. For example, a second distance DX from the side surface of each of the semiconductor chips 200 and 240 to a side surface of the molding layer 300 in the first direction X may be in a range of about 100 μm to about 10 mm.

The content percentage of the first filler 320 in the first area I may be different from the content percentage of the first filler 320 in the second area II. The content percentage of the second filler 330 in the first area I may be different from the content percentage of the second filler 330 in the second area II. For example, a ratio of the content percentage of the first filler 320 and the content percentage of the second filler 330 in the first area I may be different from a ratio of the content percentage of the first filler 320 and the content percentage of the second filler 330 in the second area II. The content percentage of each of the fillers 320 and 330 may be controlled under an electrophoretic effect (i.e., electrophoresis). This will be described in more detail later in the description of FIGS. 9 to 18.

In some embodiments, in the first area I, the content percentage of the first filler 320 may be greater than the content percentage of the second filler 330. For example, in the first area I, the ratio of the content percentage of the first filler 320 and the content percentage of the second filler 330 may be in a range of about 6:4 to about 9:1. For example, in the first area I, the ratio of the content percentage of the first filler 320 and the content percentage of the second filler 330 may be about 6:4 to about 8:2.

In some embodiments, in the second area II, the content percentage of the second filler 330 may be greater than the content percentage of the first filler 320. For example, in the second area II, a ratio of the content percentage of the first filler 320 and the content percentage of the second filler 330 may be in a range of about 1:9 to about 4:6. For example, in the second area II, the ratio of the content percentage of the first filler 320 and the content percentage of the second filler 330 may be in a range of about 1:9 to about 3:7.

Accordingly, a first portion (e.g., the first area I) of the molding layer 300 that vertically (i.e., in the third direction Z) overlaps the upper surface of the second semiconductor chip 240 (and/or the upper surface of the first semiconductor chip 200) may have a high concentration of the first fillers 320 and a low concentration of the second fillers 330. Moreover, a second portion (e.g., the second area II) of the molding layer 300 that horizontally (i.e., in the first direction X and/or the second direction Y) overlaps the side surface of the second semiconductor chip 240 (and/or the side surface of the first semiconductor chip 200) may have a low concentration of the first fillers 320 and a high concentration of the second fillers 330. The first fillers 320 may have narrow diameters, and thus may also be referred to herein as “small fillers.” The second fillers 330 may have wide diameters, and thus may also be referred to herein as “large fillers.”

In some embodiments, in the first area I, the content percentage of the first filler 320 may increase as the first area I extends away from the semiconductor chips 200 and 240 in the third direction Z. For example, the content percentage of the first filler 320 in a portion (e.g., an upper portion) of the first area I adjacent to the upper surface of the molding layer 300 may be greater than the content percentage of the first filler 320 in a portion (e.g., a lower portion) of the first area I adjacent to the semiconductor chips 200 and 240.

In some embodiments, in the first area I, the content percentage of the first filler 320 may decrease as the first area I extends toward the second area II. For example, the content percentage of the first filler 320 in a portion (e.g., an edge) of the first area I adjacent to the second area II may be smaller than the content percentage of the first filler 320 in a center portion of the first area I.

In some embodiments, in the second area II, the content percentage of the second filler 330 may decrease as the second area II extends toward the first area I. For example, the content percentage of the second filler 330 in a portion (e.g., an upper portion of the second area II) of the second area II adjacent to the first area I may be smaller than the content percentage of the second filler 330 in a lower portion of the second area II.

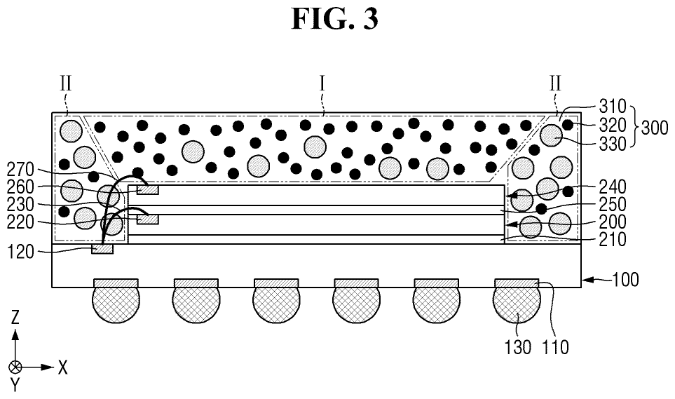

FIGS. 3 to 6 are various schematic cross-sectional views illustrating semiconductor packages according to some embodiments, respectively. For convenience of description, contents duplicate with those described above using FIGS. 1 and 2 will be briefly described or descriptions thereof are omitted.

Referring to FIG. 3, in a semiconductor package according to some embodiments, a width of the first area I may increase as the first area I extends away from the semiconductor chips 200 and 240.

For example, the width of the first area I in the first direction X may increase as the first area I extends away from the upper surface of the second semiconductor chip 240 (e.g., in the third direction Z). Accordingly, the first area I may be tapered toward the upper surface of the second semiconductor chip 240. The width of a portion (e.g., an upper portion of the second area II) of the second area II adjacent to the first area I may decrease as the portion extends toward the upper surface of the molding layer 300 (e.g., in the third direction Z).

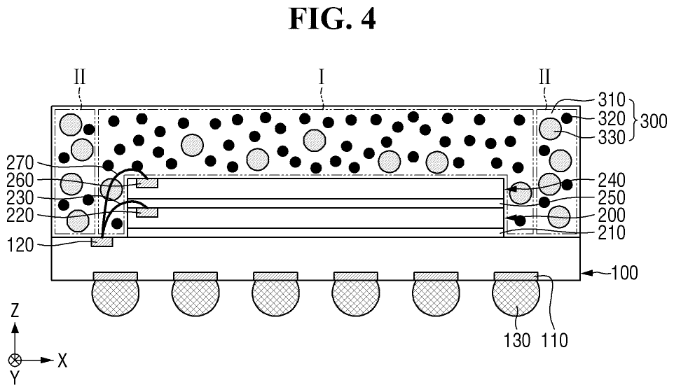

Referring to FIG. 4, in a semiconductor package according to some embodiments, a portion of the first area I may cover the side surface of each of the semiconductor chips 200 and 240.

For example, a portion of the first area I may be interposed between each of the semiconductor chips 200 and 240 and the second area II. The second area II may be spaced from the side surface of each of the semiconductor chips 200 and 240 by the portion of the first area I.

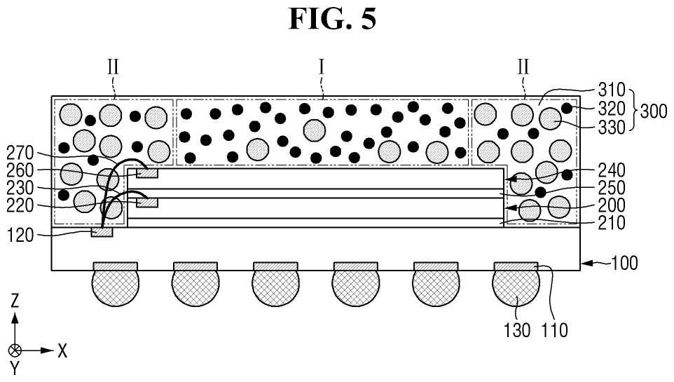

Referring to FIG. 5, in a semiconductor package according to some embodiments, a portion of the second area II may cover the upper surface of each of the semiconductor chips 200 and 240.

For example, a portion of the second area II may be disposed on the upper surface of the second semiconductor chip 240. A width in the first direction X or the second direction Y of the first area I may be smaller than a width in the first direction X or the second direction Y of each of the semiconductor chips 200 and 240.

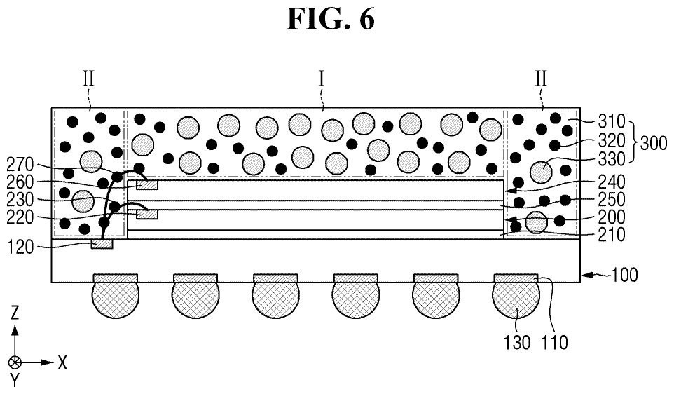

Referring to FIG. 6, in a semiconductor package according to some embodiments, in the second area II, the content percentage of the first filler 320 may be greater than the content percentage of the second filler 330.

For example, in the second area II, a ratio of the content percentage of the first filler 320 and the content percentage of the second filler 330 may be in a range of about 6:4 to about 9:1. For example, in the second area II, the ratio of the content percentage of the first filler 320 and the content percentage of the second filler 330 may be in a range of about 6:4 to about 8:2.

In some embodiments, in the first area I, the content percentage of the second filler 330 may be greater than the content percentage of the first filler 320. For example, in the first area I, the ratio of the content percentage of the first filler 320 and the content percentage of the second filler 330 may be in a range of about 1:9 to about 4:6. For example, in the first area I, the ratio of the content percentage of the first filler 320 and the content percentage of the second filler 330 may be in a range of about 1:9 to about 3:7.

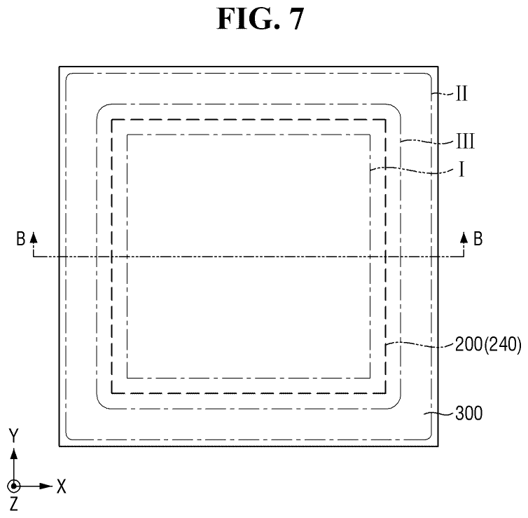

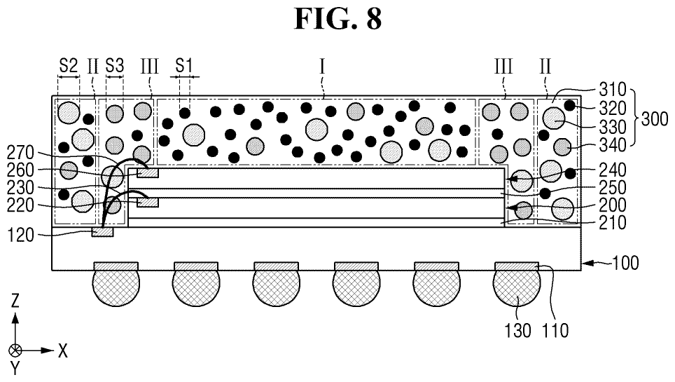

FIG. 7 is an example layout diagram for illustrating a semiconductor package according to some embodiments. FIG. 8 is a schematic cross-sectional view taken along line B-B in FIG. 7. For convenience of description, contents duplicate with those described above using FIGS. 1 to 6 will be briefly described or descriptions thereof are omitted.

Referring to FIGS. 7 and 8, in a semiconductor package according to some embodiments, the molding layer 300 may further include third fillers 340 dispersed in the molding resin 310. The third filler 340 may include the same material as that of the first filler 320 and/or the second filler 330, or may include a material different from that of the first filler 320 and/or the second filler 330. The third filler 340 may be present in a liquid or solid form (e.g., granules, powder, sheet, or tablet).

The third filler 340 may have a different size (e.g., average particle diameter) from that of each of the first filler 320 and the second filler 330. For example, the third filler 340 may have a third size S3 that is larger than the first size S1 and smaller than the second size S2.

In some embodiments, the molding layer 300 may further include a third area III. The third area III may be sandwiched between the first area I and the second area II. For example, the third area III may cover a portion of an upper surface of the semiconductor chip 240 and a side surface of each of the semiconductor chips 200 and 240.

In the first area I, the content percentage of the first filler 320 may be greater than each of the content percentage of the second filler 330 and the content percentage of the third filler 340. In the second area II, the content percentage of the second filler 330 may be greater than each of the content percentage of the first filler 320 and the content percentage of the third filler 340. In the third area III, the content percentage of the third filler 340 may be greater than the content percentage of each of the first filler 320 and the content percentage of the second filler 330.

Hereinafter, with reference to FIGS. 1 to 18, a method for manufacturing a semiconductor package according to some embodiments will be described.

FIGS. 9 to 17 are diagrams of intermediate structures corresponding to intermediate steps of a method for manufacturing a semiconductor package according to some embodiments. For convenience of description, contents duplicate with those described above using FIGS. 1 to 8 will be briefly described or descriptions thereof are omitted.

Referring to FIG. 9, a first mold 400 is provided.

The first mold 400 may include a cavity 405. The cavity 405 may provide a space in the first mold 400 for accommodating therein a molding material 300p (FIG. 10), which will be described later herein. In some embodiments, a release film 420 may be formed on the first mold 400. The release film 420 may extend along a profile of the cavity 405. The release film 420 may be used to easily remove the molding material 300p from the first mold 400 after performing a curing process/operation for the molding material 300p.

In some embodiments, an electrode pattern 410 may be disposed within the first mold 400. The electrode pattern 410 may be disposed in the first mold 400 and under the cavity 405. The electrode pattern 410 may be connected to an external power source to generate an electric field within the cavity 405.

Referring to FIG. 10, the molding material 300p is provided within the cavity 405.

The molding material 300p may fill at least a portion of the cavity 405 while being disposed on the release film 420. The molding material 300p may include epoxy molding compound (EMC) as a thermosetting resin. For example, the molding material 300p may include a pre-molding resin 310p including an epoxy resin, and the first fillers 320 and the second fillers 330 dispersed in the pre-molding resin 310p. The molding material 300p may be provided in a liquid or solid form (e.g., granules, powder, sheet, or tablet).

In some embodiments, the content percentage of the second filler 330 may be greater than the content percentage of the first filler 320. For example, a ratio of the content percentage of the first filler 320 and the content percentage of the second filler 330 may be in a range of about 1:9 to about 4:6. For example, the ratio of the content percentage of the first filler 320 and the content percentage of the second filler 330 may be in a range of about 2:8 to about 4:6.

The first filler 320 and the second filler 330 may have different sizes (e.g., different average particle diameters). For example, the first filler 320 may have the first size S1 (FIG. 2), and the second filler 330 may have the second size S2 (FIG. 2) larger than the first size S1.

The first filler 320 and the second filler 330 may have different surface charges. For example, the first filler 320 may have a surface charge of a first polarity, and the second filler 330 may have a surface charge of a neutrality or a second polarity different from the first polarity. For convenience of description, an example in which the first polarity is negative (−) is described below. However, a person skilled in the art to which the present disclosure pertains will understand that the first polarity may be positive (+).

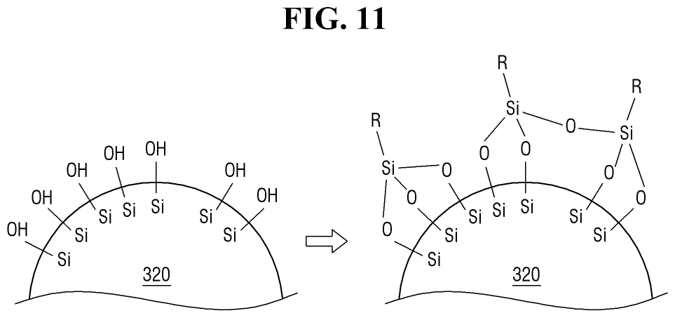

In some embodiments, at least one of the first filler 320 and the second filler 330 may be surface-treated to have a predetermined surface charge. For example, referring to FIG. 11, the second filler 330 may include silica. The surface of bare silica not subjected to the surface-treatment may have a negative (−) charge due to oxygen (O) atoms. Subsequently, a surface treatment process may be performed on the second filler 330 using a surface modifier. For example, a silane-based compound containing an organic functional group R may be used as the surface modifier. The silicon (Si) atom of the surface modifier may be coupled to the oxygen (O) atom of the silica surface, such that the second filler 330 with the organic functional group R bound to the surface thereof may be prepared. Thus, the second filler 330 having the surface that has been treated to have the predetermined surface charge may be provided.

The organic functional group R of the surface modifier may include, for example, at least one of an epoxy group, an amino group, a vinyl group, a methacryloxy group, an isocyanate group, a mercapto group, and a combination thereof. However, embodiments of the present disclosure are not limited thereto. For example, the surface modifier may include at least one of epoxy silane, phenyl silane, phenylamino silane, and combinations thereof.

In some embodiments, the first filler 320 may have a negative surface charge, and the second filler 330 may be surface treated to have a neutral surface charge. For example, the first filler 320 may include bare silica, and the second filler 330 may include silica surface-treated to have a neutral surface charge.

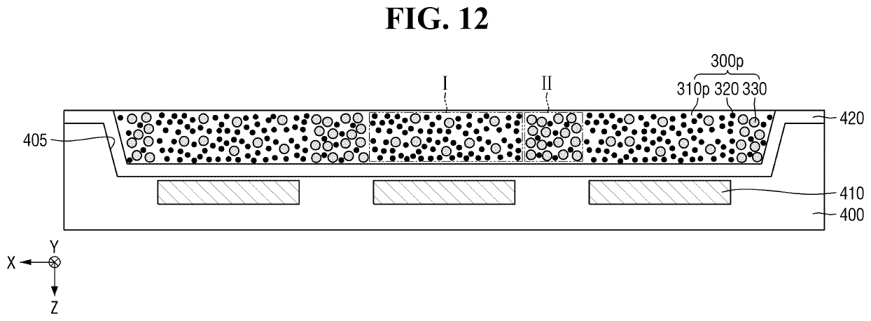

Referring to FIG. 12, using an electrophoretic effect, the first area I and the second area II may be formed such that a ratio of the content percentage of the first filler 320 and the content percentage of the second filler 330 in the first area is different from that in the second area.

For example, the molding material 300p may include the first area I and the second area II. At least a portion of the first area I may overlap the electrode pattern 410 in the third direction Z. The second area II may be defined as an area other than the first area I. For example, the second area II may not overlap the electrode pattern 410 in the third direction Z.

The electrode pattern 410 may apply an electric field to the molding material 300p. For example, the electrode pattern 410 may be provided as an electrode of the second polarity (e.g., +). In this case, the first filler 320 having the surface charge of the first polarity may be moved toward the electrode pattern 410. Accordingly, the content percentage of the first filler 320 in the first area I may be greater than the content percentage of the first filler 320 in the second area II. Furthermore, the second filler 330 which has a neutral surface charge or the second polarity surface charge may be moved in an opposite direction to a direction in which the first filler 320 moves. Accordingly, the content percentage of the second filler 330 in the second area II may be greater than the content percentage of the second filler 330 in the first area I.

In some embodiments, in the first area I, the content percentage of the first filler 320 may be greater than the content percentage of the second filler 330. In some embodiments, in the second area II, the content percentage of the second filler 330 may be greater than the content percentage of the first filler 320.

In some embodiments, the content percentage of the first filler 320 may increase as a position in the molding material 300p is closer (in the third direction Z) to the electrode pattern 410.

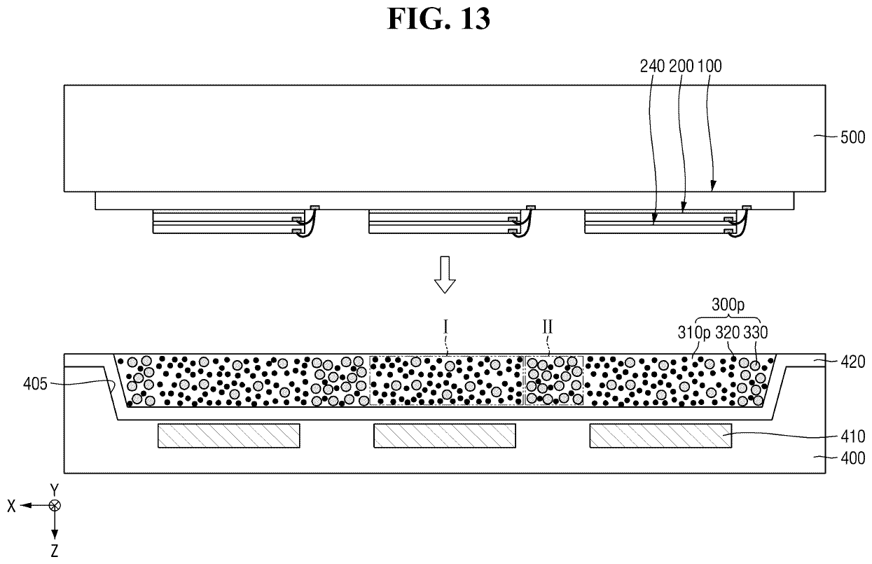

Referring to FIG. 13, a second mold 500 is provided on the first mold 400.

The semiconductor chips 200 and 240 may be disposed on the second mold 500. For example, the package substrate 100 may be disposed on the second mold 500, and the semiconductor chips 200 and 240 may be sequentially stacked on top of each other while being disposed on the package substrate 100.

The semiconductor chips 200 and 240 may constitute one chip stack on the package substrate 100. Furthermore, a plurality of chip stacks may be arranged so as to be spaced apart from each other along a horizontal direction (e.g., the first direction X or the second direction Y) while being disposed on the package substrate 100. In some embodiments, each stack of the semiconductor chips 200 and 240 may be vertically aligned with each electrode pattern 410. For example, the stack of the semiconductor chips 200 and 240 may be disposed on the second mold 500 so as to overlap the electrode pattern 410 in the third direction Z.

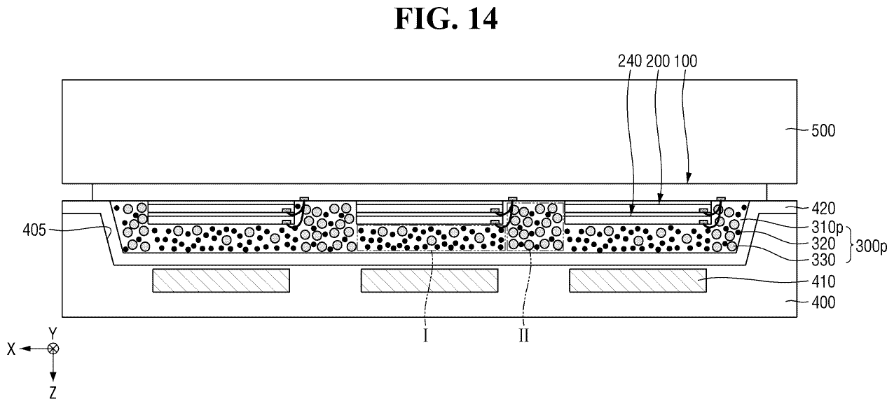

Referring to FIG. 14, a compression molding process is performed using the first mold 400 and the second mold 500.

For example, the second mold 500 may be displaced toward the first mold 400. The semiconductor chips 200 and 240 may be inserted into the cavity 405 filled with the molding material 300p. Accordingly, the molding material 300p may cover the semiconductor chips 200 and 240.

In some embodiments, at least a portion of the first area I may overlap the stack of the semiconductor chips 200 and 240 in the third direction Z. The second area II may be disposed on a side surface of the stack of the semiconductor chips 200 and 240 and a side surface of the first area I.

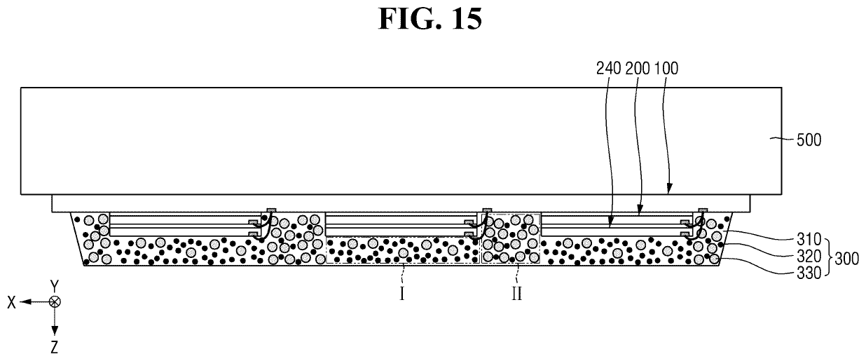

Referring to FIG. 15, the molding layer 300 is formed. The molding layer 300 may be formed by curing the molding material 300p. For example, the molding layer 300 may have the first fillers 320 and the second fillers 330 dispersed in a matrix formed by curing a liquid crystalline epoxy compound with a curing agent.

After the molding layer 300 has been formed, the release film 420 may be peeled off from the molding layer 300. Thus, the molding layer 300 may be removed from the first mold 400.

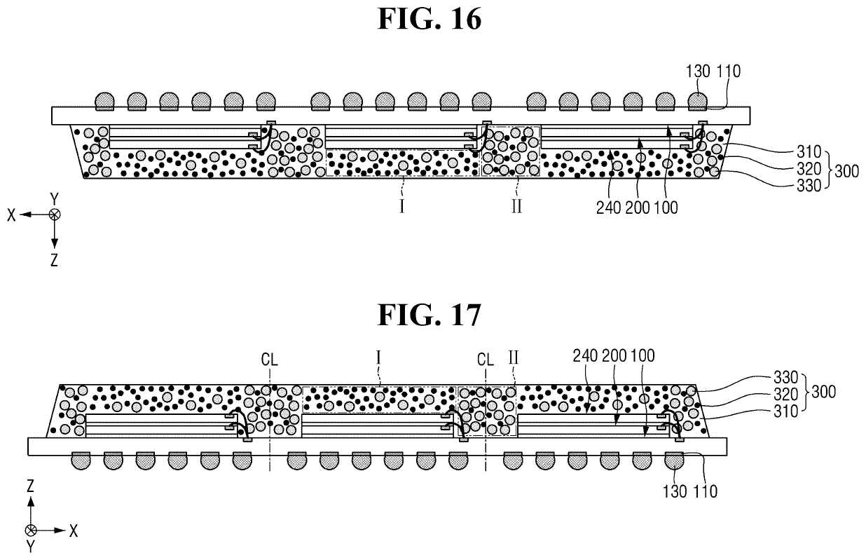

Referring to FIG. 16, the contact terminal 130 is formed on the package substrate 100.

For example, the package substrate 100 may be removed from the second mold 500. Subsequently, the first substrate pad 110 may be formed on an exposed surface of the package substrate 100. Subsequently, the contact terminal 130 attached to the first substrate pad 110 may be formed.

Referring to FIG. 17, a dicing process is performed.

For example, the package substrate 100 and the molding layer 300 may be cut along a cutting line CL. Thus, a plurality of individualized semiconductor packages may be provided.

In some embodiments, the cutting line CL may cut the second area II of the molding layer 300 sandwiched between the chip stacks. Thus, the semiconductor package described above using FIG. 1 and FIG. 2 may be provided.

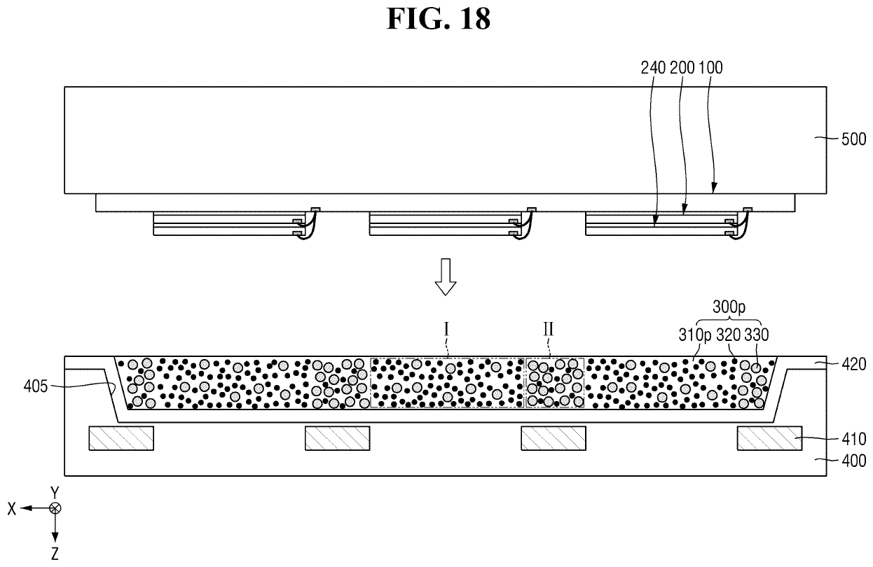

FIG. 18 is a diagram of an intermediate structure corresponding to an intermediate step of a method for manufacturing a semiconductor package according to some embodiments. For convenience of description, contents duplicate with those described above using FIGS. 1 to 17 will be briefly described or descriptions thereof are omitted.

Referring to FIG. 18, the electrode pattern 410 may be disposed to overlap at least a portion of the second area II in the third direction Z.

The first area I may be defined as an area other than the second area II. For example, the first area I may not overlap the electrode pattern 410 in the third direction Z.

The electrode pattern 410 may apply an electric field to the molding material 300p. For example, the electrode pattern 410 may be provided as an electrode of the first polarity (e.g., −). In this case, the first filler 320 with a surface charge of the first polarity may be moved away from the electrode pattern 410. Accordingly, the content percentage of the first filler 320 in the first area I may be greater than the content percentage of the first filler 320 in the second area II. Furthermore, the second filler 330 which has a neutral surface charge or the second polarity surface charge may be moved in an opposite direction to a direction in which the first filler 320 moves. Accordingly, the content percentage of the second filler 330 in the second area II may be greater than the content percentage of the second filler 330 in the first area I.

As the semiconductor package becomes lighter and thinner, a mechanical strength of the semiconductor package may weaken such that defects such as cracks may increase. These defects tend to be concentrated on an upper portion of the semiconductor package. In this regard, to improve the strength of the molding material that seals the semiconductor package, epoxy molding compound (EMC) containing relatively small-sized fillers may be used. The small-sized fillers may improve the strength of epoxy molding compound (EMC) by increasing a breaking path of the cracks. However, there is a problem that the smaller the filler size, the lower the formability of the epoxy molding compound (EMC).

In the semiconductor package according to some embodiments, the content percentage of each of the fillers 320 and 330 having different sizes may be controlled based on each of multiple areas of the molding layer 300 using an electrophoretic effect. For example, as described above, the molding layer 300 may include the first filler 320 and the second filler 330 having different sizes. In this regard, the content percentage of the first filler 320 which has a small size may be configured to be relatively high in the first area I, and may be configured to be relatively low in an area (e.g., the second area II) other than the first area I. Thus, the molding layer 300 with partially improved strength may be provided without lowering the formability.

While the present inventive concept has been particularly shown and described with reference to example embodiments thereof, it will be understood by those of ordinary skill in the art that various changes in form and details may be made therein without departing from the scope of the present inventive concept as defined by the following claims. It is therefore desired that the present embodiments be considered in all respects as illustrative and not restrictive, reference being made to the appended claims rather than the foregoing description to indicate the scope of the invention.

1. A semiconductor package comprising:
a package substrate;
a semiconductor chip mounted on the package substrate; and
a molding layer on the semiconductor chip on the package substrate, the molding layer including a first filler having a first size and a second filler having a second size larger than the first size,
wherein the molding layer includes a first area on an upper surface of the semiconductor chip, and a second area on a side surface of the first area, and
wherein a ratio of a first content percentage of the first filler and a first content percentage of the second filler in the first area is different from a ratio of a second content percentage of the first filler and a second content percentage of the second filler in the second area.

2. The semiconductor package of claim 1,
wherein in the first area, the first content percentage of the first filler is greater than the first content percentage of the second filler, and
wherein in the second area, the second content percentage of the second filler is greater than the second content percentage of the first filler.

3. The semiconductor package of claim 2, wherein in the first area, the ratio of the first content percentage of the first filler and the first content percentage of the second filler is in a range of 6:4 to 8:2.

4. The semiconductor package of claim 2, wherein in the second area, the ratio of the second content percentage of the first filler and the second content percentage of the second filler is in a range of 1:9 to 4:6.

5. The semiconductor package of claim 1,
wherein the first filler has a surface charge of a first polarity, and
wherein the second filler has a neutral surface charge or a surface charge of a second polarity different from the first polarity.

6. The semiconductor package of claim 1, wherein, in an entire area of the molding layer, a ratio of a third content percentage of the first filler and a third content percentage of the second filler is in a range of 2:8 to 4:6.

7. The semiconductor package of claim 1, wherein an average particle diameter of the first filler is in a range of 0.1 micrometers (μm) to 20 μm.

8. The semiconductor package of claim 1, wherein an average particle diameter of the second filler is in a range of 20 micrometers (μm) to 80 μm.

9. The semiconductor package of claim 1, wherein the second area surrounds a side surface of the semiconductor chip and the side surface of the first area.

10. The semiconductor package of claim 1, wherein each of the first filler and the second filler includes silica.

11. A semiconductor package comprising:
a package substrate;
a semiconductor chip mounted on the package substrate; and
a molding layer on the semiconductor chip on the package substrate, the molding layer including a first filler having a first size and a second filler having a second size larger than the first size,
wherein the molding layer includes a first area on an upper surface of the semiconductor chip, and a second area surrounding a side surface of the semiconductor chip and a side surface of the first area,
wherein in the first area, a first content percentage of the first filler is greater than a first content percentage of the second filler, and
wherein in the second area, a second content percentage of the second filler is greater than a second content percentage of the first filler.

12. The semiconductor package of claim 11, wherein in the first area, a ratio of the first content percentage of the first filler and the first content percentage of the second filler is in a range of 6:4 to 8:2.

13. The semiconductor package of claim 11, wherein in the second area, a ratio of the second content percentage of the first filler and the second content percentage of the second filler is in a range of 1:9 to 4:6.

14. The semiconductor package of claim 11, wherein, in an entire area of the molding layer, a ratio of a third content percentage of the first filler and a third content percentage of the second filler is in a range of 2:8 to 4:6.

15. The semiconductor package of claim 11, wherein an average particle diameter of the first filler is in a range of 0.1 micrometers (μm) to 20 μm.

16. The semiconductor package of claim 11, wherein an average particle diameter of the second filler is in a range of 20 micrometers (μm) to 80 μm.

17. The semiconductor package of claim 11,
wherein the molding layer further includes a third filler having a third size larger than the first size and smaller than the second size,
wherein the molding layer further includes a third area interposed between the first area and the second area, and
wherein in the third area, a content percentage of the third filler is greater than each of a third content percentage of the first filler and a third content percentage of the second filler.

18. The semiconductor package of claim 11, wherein in the first area, the first content percentage of the first filler increases as the first area extends away from the upper surface of the semiconductor chip.

19. The semiconductor package of claim 11, wherein a width of the first area increases as the first area extends away from the upper surface of the semiconductor chip.

20-25. (canceled)

26. A semiconductor package comprising:
a package substrate;
a semiconductor chip on the package substrate; and
a molding layer on an upper surface and a side surface of the semiconductor chip, and on an upper surface of the package substrate, the molding layer including small fillers having a narrow diameter and large fillers having a wide diameter,
wherein a first portion of the molding layer that vertically overlaps the upper surface of the semiconductor chip has a high concentration of the small fillers and a low concentration of the large fillers, and
wherein a second portion of the molding layer that horizontally overlaps the side surface of the semiconductor chip has a low concentration of the small fillers and a high concentration of the large fillers.
